(19) United States
(12) Patent Application Publication
(10) Pub. No.: US 2012/0047092 A1
(43) Pub. Date: Feb. 23, 2012

(54) METHODS, SYSTEMS, AND COMPUTER PROGRAM PRODUCTS FOR PRESENTING AN INDICATION OF A COST OF PROCESSING A RESOURCE

(76) Inventor: Robert Paul Morris, Raleigh, NC (US)

(21) Appl. No.: 12/857,847

(22) Filed: Aug. 17, 2010

(51) Int. Cl. G06F 17/00; G01R 21/00; G06F 19/00; G06F 3/048

(52) U.S. Cl. 705/400; 715/772; 702/60

(57) ABSTRACT

Methods and systems are described for presenting an indication of a cost of processing a resource. Resource information is received that identifies a resource for processing by a hardware component in performing an operation. A measure of a processing cost is determined for the resource based on the operation, to provide an indication of a cost for processing the resource. Presentation information, based on the measure, is sent to present, via an output device, the indication corresponding to a user detectable representation of the resource.

### RELATED APPLICATIONS

This application is related to the following commonly owned U.S. patent applications, the entire disclosure of each being incorporated by reference herein: application Ser. No. ______, (Docket No 0137) filed on Aug. 17, 2010, entitled “Methods, Systems, and Program Products for Selecting a Resource in Response to a Change in Available Energy”;

Application Ser. No. ______, (Docket No 0162) filed on Aug. 17, 2010, entitled “Methods, Systems, and Program Products for Selecting a Resource Based on a Measure of a Processing Cost”; and

Application Ser. No. ______, (Docket No 0123) filed on Aug. 17, 2010, entitled “Methods, Systems, and Program Products for Maintaining a Resource Based on a Cost of Energy”.

### BACKGROUND

Many current computing devices are capable of adjusting to changes in levels of power received from and/or energy available in batteries. A number of devices are capable of adjusting to a switch between receiving energy from a battery and receiving energy from a power outlet. These changes are restricted to adjusting parameters for particular components, such as the brightness level of a display, or simply turning a feature on or off.

Current devices do not give consideration to the effects that processing of particular resources such a files, images, and videos have on energy management. In particular, current systems give no consideration to relative differences in energy utilization of various alternative resources including services provided by software and/or hardware components in energy management. Current devices and systems provide the alternative of operating a feature or not.

Accordingly, there exists a need for methods, systems, and computer program products for presenting an indication of a cost of processing a resource.

### SUMMARY

The following presents a simplified summary of the disclosure in order to provide a basic understanding to the reader. This summary is not an extensive overview of the disclosure, and it does not identify key/critical elements of the invention or delineate the scope of the invention. Its sole purpose is to present some concepts disclosed herein in a simplified form as a prelude to the more detailed description that is presented later.

Methods and systems are described for presenting an indication of a cost of processing a resource. In one aspect, the method includes receiving resource information identifying a resource for processing by a hardware component in performing an operation. The method further includes determining, for the resource, a measure of a processing cost, based on the operation, to provide an indication of the cost for processing the resource. The method still further includes sending presentation information, based on the measure, for presenting, via an output device, the indication corresponding to a user detectable representation of the resource.

Further, a system for presenting an indication of a cost of processing a resource is described. The system includes a cost advisor component, a cost monitor component, and a cost presentation component adapted for operation in an execution environment. The system includes the cost advisor component configured for receiving resource information identifying a resource for processing by a hardware component in performing an operation. The system further includes the cost monitor component configured for determining, for the resource, a measure of a processing cost, based on the operation, to provide an indication of the cost for processing the resource. The system still further includes the cost presentation component configured for sending presentation information, based on the measure, for presenting, via an output device, the indication corresponding to a user detectable representation of the resource.

### BRIEF DESCRIPTION OF THE DRAWINGS

Objects and advantages of the present invention will become apparent to those skilled in the art upon reading this description in conjunction with the accompanying drawings, in which like reference numerals have been used to designate like or analogous elements, and in which:

FIG. 1 is a block diagram illustrating an exemplary hardware device included in and/or otherwise providing an execution environment in which the subject matter may be implemented;

FIG. 2 is a flow diagram illustrating a method for presenting an indication of a cost of processing a resource according to an aspect of the subject matter described herein;

FIG. 3 is a block diagram illustrating an arrangement of components for presenting an indication of a cost of processing a resource according to another aspect of the subject matter described herein;

FIG. 4a is a block diagram illustrating an arrangement of components for presenting an indication of a cost of processing a resource according to another aspect of the subject matter described herein;

FIG. 4b is a block diagram illustrating an arrangement of components for presenting an indication of a cost of processing a resource according to another aspect of the subject matter described herein;

FIG. 4c is a block diagram illustrating an arrangement of components for presenting an indication of a cost of processing a resource according to another aspect of the subject matter described herein;

FIG. 4d is a block diagram illustrating an arrangement of components for presenting an indication of a cost of processing a resource according to another aspect of the subject matter described herein;

FIG. 5 is a network diagram illustrating an exemplary system for presenting an indication of a cost of processing a resource according to another aspect of the subject matter described herein; and

FIG. 6 is a diagram illustrating a user interface presented via a display according to another aspect of the subject matter described herein.

### DETAILED DESCRIPTION

One or more aspects of the disclosure are described with reference to the drawings, wherein like reference numerals are generally utilized to refer to like elements throughout, and wherein the various structures are not necessarily drawn to scale. In the following description, for purposes of explanation, numerous specific details are set forth in order to provide a thorough understanding of one or more aspects of the disclosure. It may be evident, however, to one skilled in the art, that one or more aspects of the disclosure may be practiced with a lesser degree of these specific details. In other instances, well-known structures and devices are shown in block diagram form in order to facilitate describing one or more aspects of the disclosure.

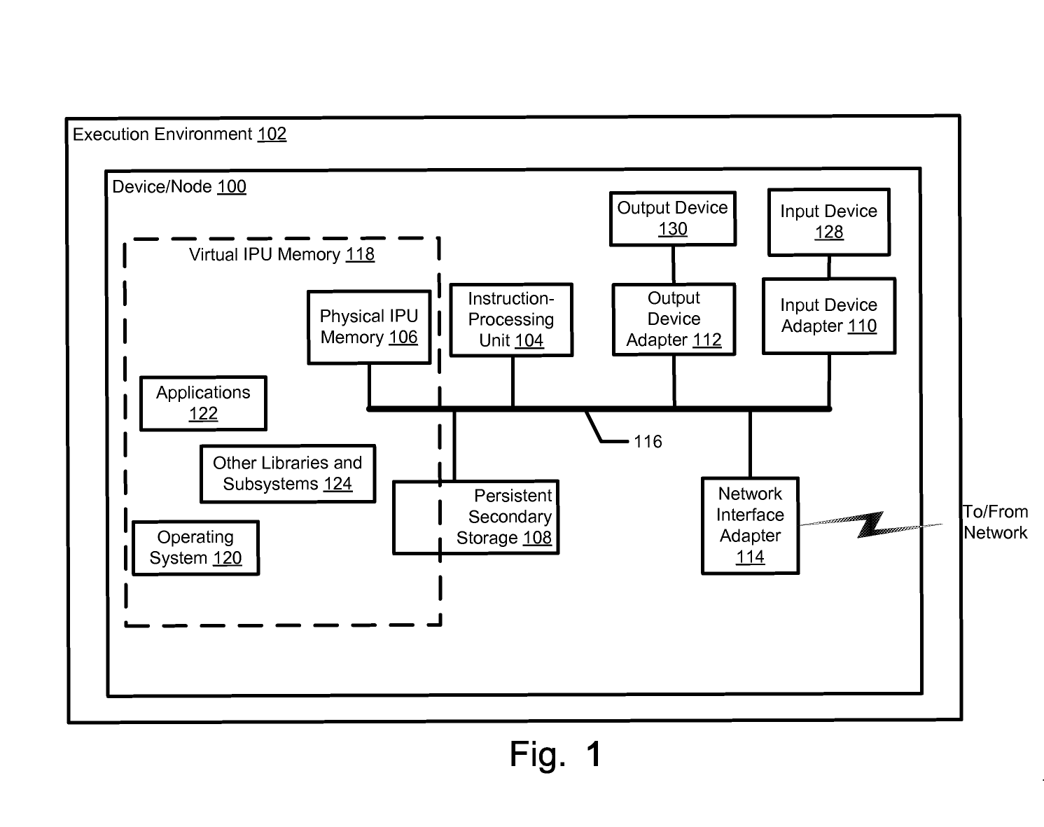

An exemplary device included in an execution environment that may be configured according to the subject matter is illustrated in FIG. 1. An execution environment includes an arrangement of hardware and, optionally, software that may be further configured to include an arrangement of components for performing a method of the subject matter described herein. An execution environment includes and/or is otherwise provided by one or more devices. An execution environment may include a virtual execution environment including software components operating in a host execution environment. Exemplary devices included in or otherwise providing suitable execution environments for configuring according to the subject matter include personal computers, notebook computers, tablet computers, servers, handheld and other mobile devices, multiprocessor devices, distributed devices, consumer electronic devices, routers, communication servers, and/or other network-enabled devices. Those skilled in the art will understand that the components illustrated in FIG. 1 are exemplary and may vary by particular execution environment.

FIG. 1 illustrates hardware device 100 included in execution environment 102. FIG. 1 illustrates that execution environment 102 includes instruction-processing unit (IPU) 104, such as one or more microprocessors; physical IPU memory 106 including storage locations identified by addresses in a physical memory address space of IPU 104; persistent secondary storage 108, such as one or more hard drives and/or flash storage media; input device adapter 110, such as a key or keypad hardware, a keyboard adapter, and/or a mouse adapter; output device adapter 112, such as a display and/or an audio adapter for presenting information to a user; a network interface component, illustrated by network interface adapter 114, for communicating via a network such as a LAN and/or WAN; and a communication mechanism that couples elements 104-114, illustrated as bus 116. Elements 104-114 may be operatively coupled by various means. Bus 116 may comprise any type of bus architecture, including a memory bus, a peripheral bus, a local bus, and/or a switching fabric.

IPU 104 is an instruction execution machine, apparatus, or device. Exemplary IPUs include one or more microprocessors, digital signal processors (DSPs), graphics processing units, application-specific integrated circuits (ASICs), and/or field programmable gate arrays (FPGAs). In the description of the subject matter herein, the terms “IPU” and “processor” are used interchangeably. IPU 104 may access machine code instructions and data via one or more memory address spaces in addition to the physical memory address space. A memory address space includes addresses identifying locations in a processor memory. The addresses in a memory address space are included in defining a processor memory. IPU 104 may have more than one processor memory. Thus, IPU 104 may have more than one memory address space. IPU 104 may access a location in a processor memory by processing an address identifying the location. The processed address may be in an operand of a machine code instruction and/or may be identified in a register or other portion of IPU 104.

FIG. 1 illustrates virtual IPU memory 118 spanning at least part of physical IPU memory 106 and at least part of persistent secondary storage 108. Virtual memory addresses in a memory address space may be mapped to physical memory addresses identifying locations in physical IPU memory 106. An address space for identifying locations in a virtual processor memory is referred to as a virtual memory address space; its addresses are referred to as virtual memory addresses; and its IPU memory is referred to as a virtual IPU memory or virtual memory. The terms “IPU memory” and “processor memory” are used interchangeably herein. Processor memory may refer to physical processor memory, such as IPU memory 106, and/or may refer to virtual processor memory, such as virtual IPU memory 118, depending on the context in which the term is used.

Physical IPU memory 106 may include various types of memory technologies. Exemplary memory technologies include static random access memory (SRAM) and/or dynamic RAM (DRAM) including variants such as dual data rate synchronous DRAM (DDR SDRAM), error correcting code synchronous DRAM (ECC SDRAM), and/or RAMBUS DRAM (RDRAM). Physical IPU memory 106 may include volatile memory as illustrated in the previous sentence and/or may include nonvolatile memory such as nonvolatile flash RAM (NVRAM) and/or ROM.

Persistent secondary storage 108 may include one or more flash memory storage devices, one or more hard disk drives, one or more magnetic disk drives, and/or one or more optical disk drives. Persistent secondary storage may include removable media. The drives and their associated computer readable storage media provide volatile and/or nonvolatile storage for computer readable instructions, data structures, program components, and other data for execution environment 102.

Execution environment 102 may include software components stored in persistent secondary storage 108, in remote storage accessible via a network, and/or in a processor memory. FIG. 1 illustrates execution environment 102 including operating system 120, one or more applications 122, and other program code and/or data components illustrated by other libraries and subsystems 124. In an aspect, some or all software components may be stored in locations accessible to IPU 104 in a shared memory address space shared by the software components. The software components accessed via the shared memory address space are stored in a shared processor memory defined by the shared memory address space. In another aspect, a first software component may be stored in one or more locations accessed by IPU 104 in a first address space and a second software component may be stored in one or more locations accessed by IPU 104 in a second address space. The first software component is stored in a first processor memory defined by the first address space and the second software component is stored in a second processor memory defined by the second address space.

Software components typically include instructions executed by IPU 104 in a computing context referred to as a “process”. A process may include one or more “threads”. A “thread” includes a sequence of instructions executed by IPU 104 in a computing sub-context of a process. The terms “thread” and “process” may be used interchangeably herein when a process includes only one thread.

Execution environment 102 may receive user-provided information via one or more input devices illustrated by input device 128. Input device 128 provides input information to other components in execution environment 102 via input device adapter 110. Execution environment 102 may include an input device adapter for a keyboard, a touch screen, a microphone, a joystick, a television receiver, a video camera, a still camera, a document scanner, a fax, a phone, a modem, a network interface adapter, and/or a pointing device, to name a few exemplary input devices.

Input device 128 included in execution environment 102 may be included in device 100 as FIG. 1 illustrates or may be external (not shown) to device 100. Execution environment 102 may include one or more internal and/or external input devices. External input devices may be connected to device 100 via corresponding communication interfaces such as a serial port, a parallel port, and/or a universal serial bus (USB) port. Input device adapter 110 receives input and provides a representation to bus 116 to be received by IPU 104, physical IPU memory 106, and/or other components included in execution environment 102.

Output device 130 in FIG. 1 exemplifies one or more output devices that may be included in and/or may be external to and operatively coupled to device 100. For example, output device 130 is illustrated connected to bus 116 via output device adapter 112. Output device 130 may be a display device. Exemplary display devices include liquid crystal displays (LCDs), light emitting diode (LED) displays, and projectors. Output device 130 presents output of execution environment 102 to one or more users. In some embodiments, an input device may also include an output device. Examples include a phone, a joystick, and/or a touch screen. In addition to various types of display devices, exemplary output devices include printers, speakers, tactile output devices such as motion producing devices, and other output devices producing sensory information detectable by a user.

A device included in or otherwise providing an execution environment may operate in a networked environment communicating with one or more devices via one or more network interface components. The terms “communication interface component” and “network interface component” are used interchangeably. FIG. 1 illustrates network interface adapter (NIA) 114 as a network interface component included in execution environment 102 to operatively couple device 100 to a network. A network interface component includes a network interface hardware (NIH) component and optionally a software component.

Exemplary network interface components include network interface controller components, network interface cards, network interface adapters, and line cards. A node may include one or more network interface components to interoperate with a wired network and/or a wireless network. Exemplary wireless networks include a BLUETOOTH network, a wireless 802.11 network, and/or a wireless telephony network (e.g., a cellular, PCS, CDMA, and/or GSM network). Exemplary network interface components for wired networks include Ethernet adapters, Token-ring adapters, FDDI adapters, asynchronous transfer mode (ATM) adapters, and modems of various types. Exemplary wired and/or wireless networks include various types of LANs, WANs, and/or personal area networks (PANs). Exemplary networks also include intranets and internets such as the Internet.

The terms “network node” and “node” in this document both refer to a device having a network interface component for operatively coupling the device to a network. Further, the terms “device” and “node” used herein refer to one or more devices and nodes, respectively, providing and/or otherwise included in an execution environment unless clearly indicated otherwise.

The components of a user interface are generically referred to herein as “user interface elements”. More specifically, visual components of a user interface are referred to herein as “visual interface elements”. A visual interface element may be a visual component of a graphical user interface (GUI). Exemplary visual interface elements include windows, textboxes, sliders, list boxes, drop-down lists, spinners, various types of menus, toolbars, ribbons, combo boxes, tree views, grid views, navigation tabs, scrollbars, labels, tooltips, text in various fonts, balloons, dialog boxes, and various types of button controls including check boxes and radio buttons. An application interface may include one or more of the elements listed. Those skilled in the art will understand that this list is not exhaustive. The terms “visual representation”, “visual component”, and “visual interface element” are used interchangeably in this document. Other types of user interface elements include audio output components referred to as “audio interface elements”, tactile output components referred to as “tactile interface elements”, and the like.

A “user interface (UI) element handler” component, as the term is used in this document, includes a component configured to send information representing a program entity for presenting a user detectable representation of the program entity by an output device, such as a display. A “program entity” is an object included in and/or otherwise processed by an application or executable. The user detectable representation is presented based on the sent information. The sent information is referred to herein as “presentation information”. Presentation information may include data in one or more formats. Exemplary formats include image formats such as JPEG, video formats such as MP4, markup language data such as HTML and other XML-based markup, and/or instructions such as those defined by various script languages, byte code, and/or machine code. For example, a web page received by a browser from a remote application provider may include HTML ECMAScript, and/or byte code for presenting one or more user interface elements included in a user interface of the remote application. Components configured to send information representing one or more program entities for presenting particular types of output by particular types of output devices include visual interface elements, audio interface element handler components, tactile interface element handler components, and the like.

A representation of a program entity may be stored and/or otherwise maintained in a presentation space. As used in this document, the term “presentation space” refers to a storage region allocated and/or otherwise provided for storing presentation information, which may include audio, visual, tactile, and/or other sensory data for presentation by and/or on an output device. For example, a buffer for storing an image and/or text string may be a presentation space. A presentation space may be physically and/or logically contiguous or non-contiguous. A presentation space may have a virtual as well as a physical representation. A presentation space may include a storage location in processor memory, secondary storage, a memory of an output adapter device, and/or a storage medium of an output device. A screen of a display, for example, is a presentation space.

As used herein, the term “program” or “executable” refers to any data representation that may be translated into a set of machine code instructions and optionally associated program data. Thus, a program or executable may include an application, a shared or non-shared library, and a system command. Program representations other than machine code include object code, byte code, and source code. Object code includes a set of instructions and/or data elements that either are prepared for linking prior to loading or are loaded into an execution environment. When in an execution environment, object code may include references resolved by a linker and/or may include one or more unresolved references. The context in which this term is used will make clear that state of the object code when it is relevant. This definition can include machine code and virtual machine code, such as Java™ byte code.

As used herein, an “addressable entity” is a portion of a program, specifiable in programming language in source code. An addressable entity is addressable in a program component translated for a compatible execution environment from the source code. Examples of addressable entities include variables, constants, functions, subroutines, procedures, modules, methods, classes, objects, code blocks, and labeled instructions. A code block includes one or more instructions in a given scope specified in a programming language. An addressable entity may include a value. In some places in this document “addressable entity” refers to a value of an addressable entity. In these cases, the context will clearly indicate that the value is being referenced.

Addressable entities may be written in and/or translated to a number of different programming languages and/or representation languages, respectively. An addressable entity may be specified in and/or translated into source code, object code, machine code, byte code, and/or any intermediate languages for processing by an interpreter, compiler, linker, loader, or analogous tool.

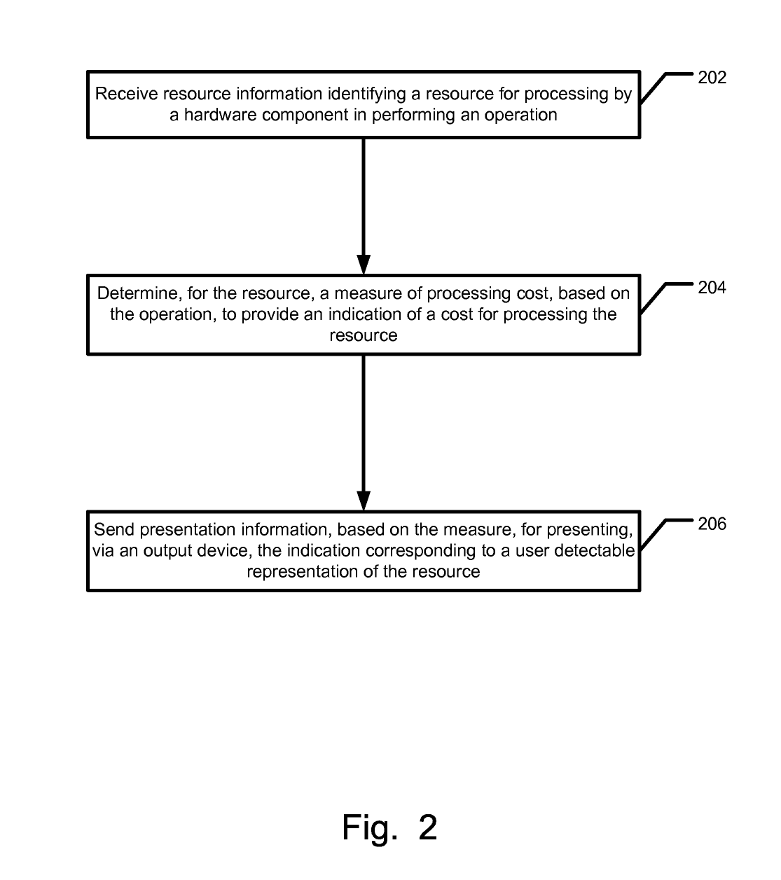

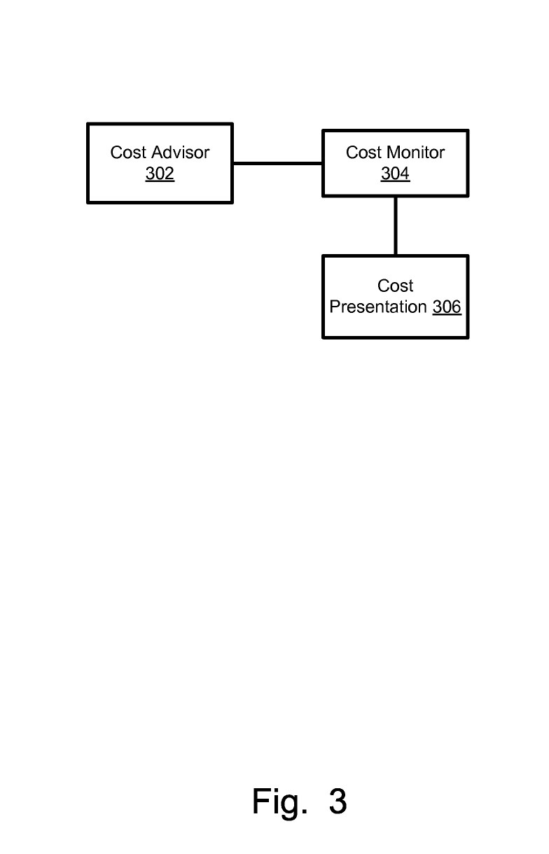

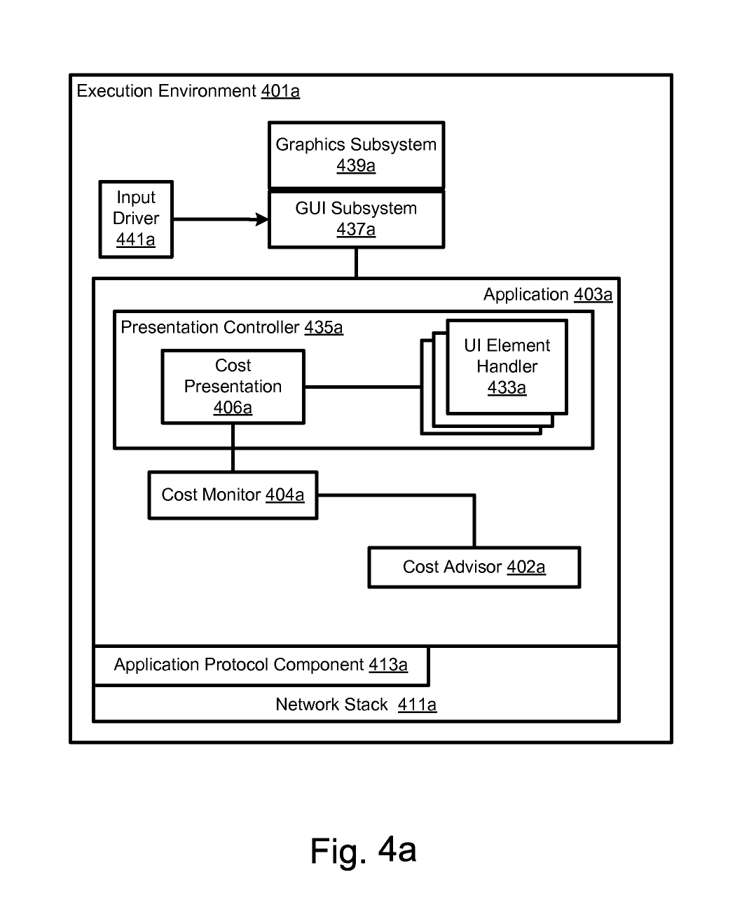

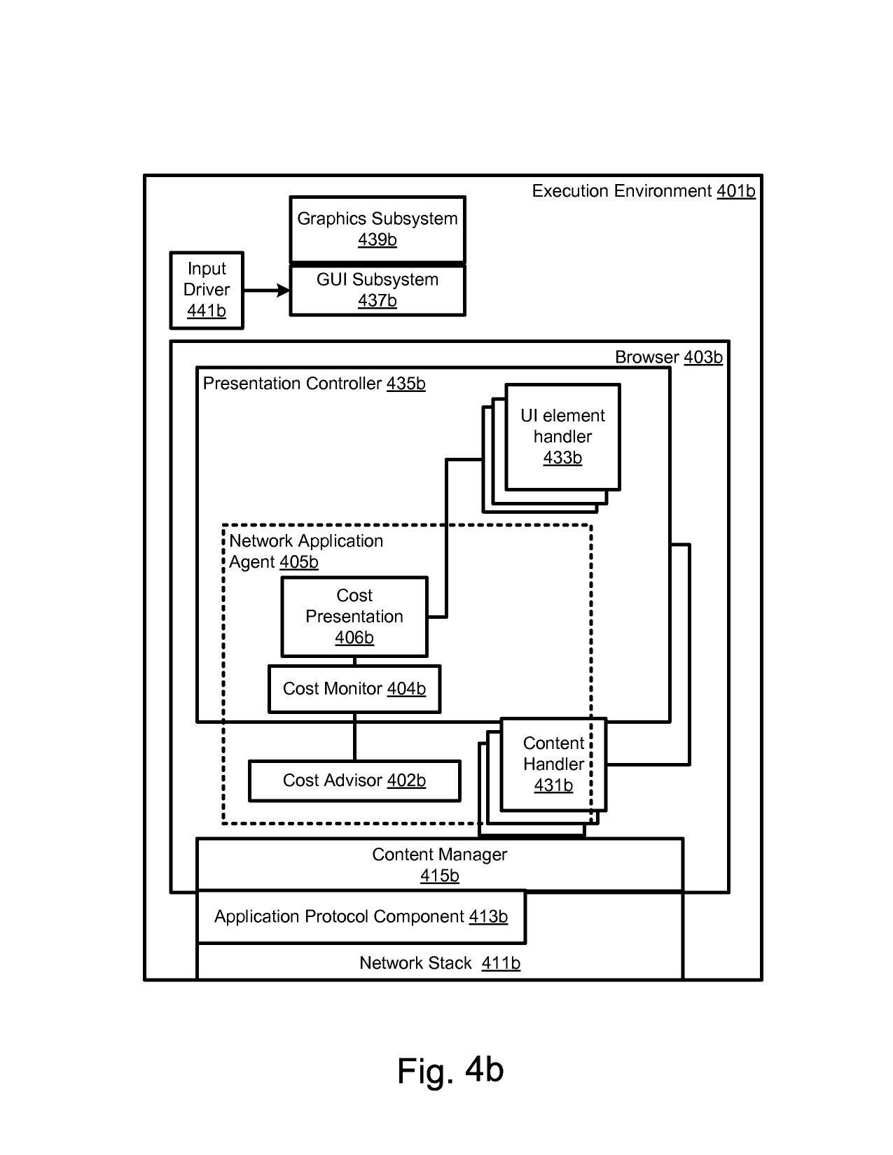

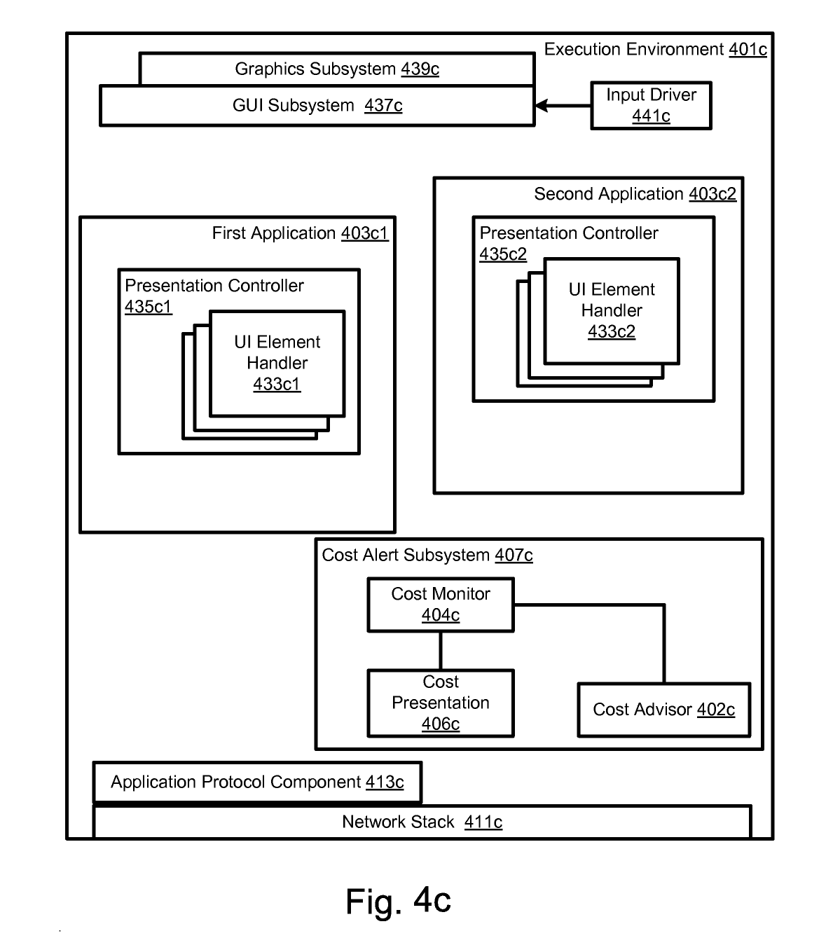

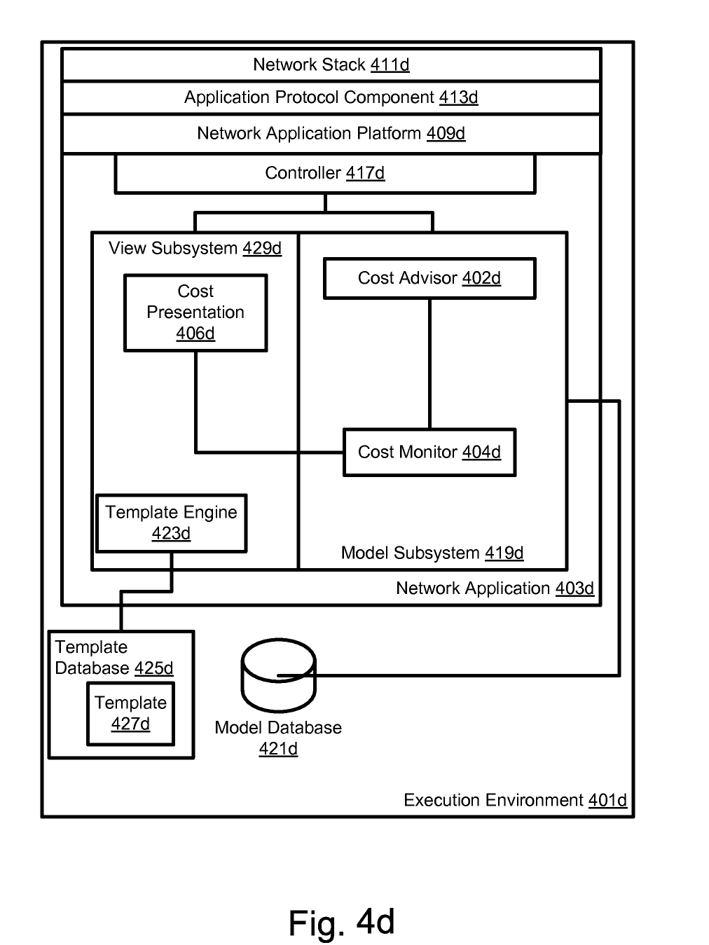

The block diagram in FIG. 3 illustrates an exemplary system for presenting an indication of a cost of processing a resource according to the method illustrated in FIG. 2. FIG. 3 illustrates a system, adapted for operation in an execution environment, such as execution environment 102 in FIG. 1, for performing the method illustrated in FIG. 2. The system illustrated includes a cost advisor component 302, a cost monitor component 304, and a cost presentation component 306. The execution environment includes an instruction-processing unit, such as IPU 104, for processing an instruction in at least one of the cost advisor component 302, the cost monitor component 304, and the cost presentation component 306. Some or all of the exemplary components illustrated in FIG. 3 may be adapted for performing the method illustrated in FIG. 2 in a number of execution environments. FIGS. 4a-d include block diagrams illustrating the components of FIG. 3 and/or analogs of the components of FIG. 3 adapted for operation in various execution environments 401 including or otherwise provided by one or more nodes.

FIG. 1 illustrates components of an exemplary device that may at least partially provide and/or otherwise be included in an execution environment. The components illustrated in FIGS. 4a-d may be included in or otherwise combined with the components of FIG. 1 to create a variety of arrangements of components according to the subject matter described herein.

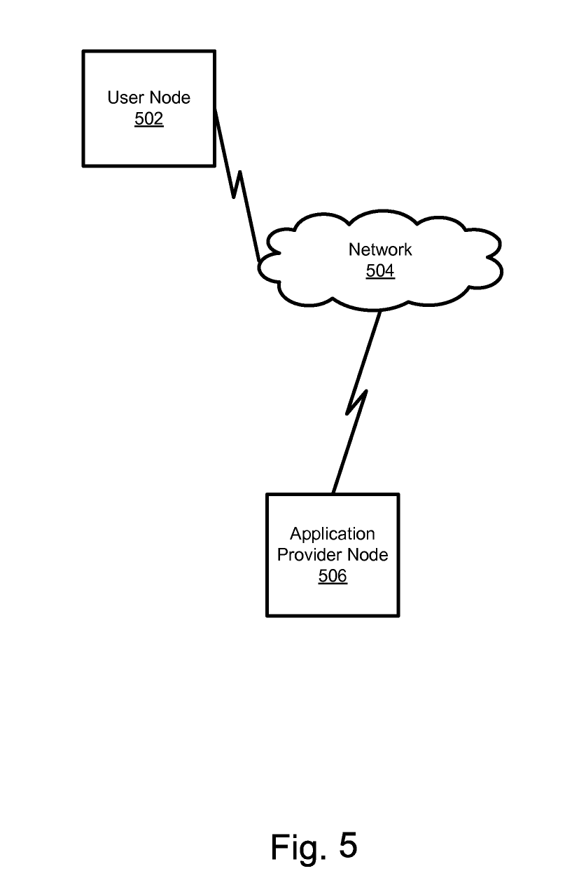

FIG. 5 illustrates user node 502 as an exemplary device that in various aspects may be included in and/or otherwise adapted for providing any of execution environments 401 illustrated in FIGS. 4a-c each illustrating a different adaptation of the arrangement of components in FIG. 3. As illustrated in FIG. 5, user node 502 is operatively coupled to network 504 via a network interface component, such as network interface adapter 114. Alternatively or additionally, an adaptation of an execution environment 401 may include and/or may otherwise be provided by a device that is not operatively coupled to a network. A server device is illustrated by application provider node 506. Application provider node 506 may be included in and/or otherwise adapted for providing execution environment 401d illustrated in FIG. 4d. As illustrated in FIG. 5, application provider node 506 is operatively coupled to network 504 via a network interface component included in execution environment 401d.

FIG. 4a illustrates execution environment 401a hosting application 403a including an adaptation of the arrangement of components in FIG. 3. FIG. 4b illustrates execution environment 401b hosting browser 403b including an adaptation of the arrangement of components in FIG. 3 that may operate at least partially in a network application agent 405b received from a remote application provider, such as network application 403d in FIG. 4d. Browser 403b and execution environment 401b may provide at least part of an execution environment for network application agent 405b that may be received via a network from a network application operating in a remote execution environment. FIG. 4c illustrates an arrangement of the components in FIG. 3 adapted to operate in a cost alert subsystem 407c of execution environment 401c.

FIG. 4d illustrates execution environment 401d configured to host one or more network applications, such as a web service, illustrated by network application 403d. FIG. 4d also illustrates network application platform 409d that may provide services to one or more network applications. Network application 403d includes yet another adaptation of the arrangement of components in FIG. 3.

The various adaptations of the arrangement in FIG. 3 that are described herein are not exhaustive. For example, those skilled in the art will see based on the description herein that arrangements of components for performing the method illustrated in FIG. 2 may be at least partially included in an application and at least partially external to the application. Further, arrangements for performing the method illustrated in FIG. 2 may be distributed across more than one node and/or execution environment. For example, such an arrangement may operate at least partially in browser 403b in FIG. 4b and at least partially in execution environment 401d in and/or external to network application 403d.

FIGS. 4a-d illustrate adaptations of network stacks 411 configured for sending and receiving messages over a network, such as network 504, via a network interface component. Network application platform 409d in FIG. 4d provides services to one or more network applications. In various aspects, network application platform 409d may include and/or interoperate with a web server. FIG. 4d also illustrates network application platform 409d configured for interoperating with network stack 411d.

Network stacks 411 may support the same protocol suite, such as TCP/IP, or may communicate via a network gateway or other protocol translation device and/or service. For example, browser 403b in FIG. 4b and network application platform 409d in FIG. 4d may interoperate via their respective network stacks: network stack 411b and network stack 411d.

FIGS. 4a-d illustrate applications 403, respectively, which may communicate via one or more application layer protocols. FIGS. 4a-d respectively illustrate application protocol components 413 for communicating via one or more application layer protocols. Exemplary application protocols include hypertext transfer protocol (HTTP) and instant messaging and presence (XMPP-IM) protocol. Matching protocols enabling applications 403 to communicate via network 504 in FIG. 5 are not required, if communication is via a protocol gateway or other translator.

In FIG. 4b, browser 403b may receive some or all of network application agent 405b in one or more messages sent from a network application, such as network application 403d via network application platform 409d, a network stack 411, a network interface component, and optionally an application protocol component 413. In FIG. 4b, browser 403b includes content manager component 415b. Content manager component 415b may interoperate with one or more of application protocol components 413b and/or network stack 411b to receive the message or messages including some or all of network application agent 405b.

Network application agent 405b may include a web page for presenting a user interface for network application 403d. The web page may include and/or reference data represented in one or more formats including hypertext markup language (HTML) and/or other markup language, ECMAScript and/or other scripting language, byte code, image data, audio data, and/or machine code.

In an example, in response to a request received from browser 403b, controller component 417d, in FIG. 4d, may invoke model subsystem 419d to perform request-specific processing. Model subsystem 419d may include any number of request handlers (not shown) for dynamically generating data and/or retrieving data from model database 421d based on the request. Controller component 417d may further invoke template engine 423d to identify one or more templates and/or static data elements for generating a user interface for representing a response to the received request. FIG. 4d illustrates template database 425d including exemplary template 427d. FIG. 4d illustrates template engine 423d as a component in view subsystem 429d configured to return responses to processed requests in a presentation format suitable for a client, such as browser 403b. View subsystem 429d may provide the presentation data to controller component 417d to send to browser 403b in response to the request received from browser 403b. Some or all of network application agent 405b may be sent to browser 403b via network application platform 409d as described above.

While the example describes sending some or all of network application agent 405b in response to a request, network application 403d additionally or alternatively may send some or all of a network application agent to browser 403b via one or more asynchronous messages. In an aspect, an asynchronous message may be sent in response to a change detected by network application 403d. Publish-subscribe protocols, such as the presence protocol specified by XMPP-IM, are exemplary protocols for sending messages asynchronously.

The one or more messages including information representing some or all of network application agent 405b in FIG. 4b may be received by content manager component 415b via one or more of application protocol component(s) 413b and network stack 411b as described above. In FIG. 4b, browser 403b includes one or more content handler components 431b to process received data according to its data type, typically identified by a MIME-type identifier. Exemplary content handler components 431b include a text/html content handler component for processing HTML documents; an application/xmpp-xml content handler component for processing XMPP streams including presence tuples, instant messages, and publish-subscribe data as defined by various XMPP specifications; one or more video content handler components for processing video streams of various types; and still image data content handler components for processing various images types. Content handler components 431b process received data and may provide a representation of the processed data to one or more user interface (UI) element handler components 433b.

UI element handler components 433 are respectively illustrated in presentation controller components 435 in FIG. 4a, FIG. 4b, and FIG. 4c. A presentation controller component 435 may manage visual, audio, and/or other types of output of its including application 403 as well as receive and route detected user and other inputs to components and extensions of its including application 403. With respect to FIG. 4b, a UI element handler component 433b in various aspects may be adapted to operate at least partially in a content handler component 431b such as a text/html content handler component and/or a script content handler component. Additionally or alternatively, a UI element handler component 433 in an execution environment 401 may operate in and/or as an extension of its including application 403. For example, a plug-in may provide a virtual machine, for a UI element handler component received as a script and/or byte code, that may operate as an extension in application 403 and/or external to and interoperating with application 403.

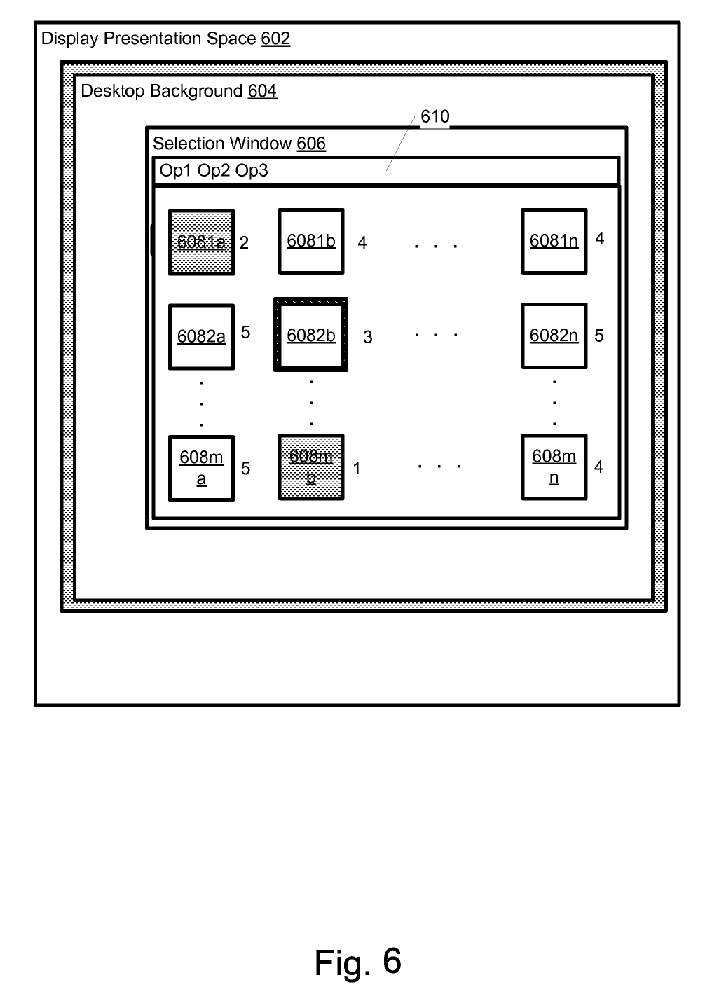

FIG. 6 illustrates display presentation space 602 of a display in and/or operatively coupled to user node 502. FIG. 6 illustrates desktop background 604 that may be a still image and/or a video background. Selection window 606 is illustrated including selectable resource icons 608. In an aspect, a resource icon may represent image and/or video data. Resource icon 6082b is illustrated as selected. A selected image file and/or video stream that corresponds to a selected resource icon 608 may be processed in response to user input corresponding to operations illustrated in operation bar 610. Selection window 606 may be a user interface presented by any of applications 403 illustrated in FIGS. 4a-d and/or by network application agent 405b. For example, selection window 606 may be presented via interoperation of browser 403b, network application agent 405b, and/or network application 403d. A browser window may include a user interface of a network application provided by a remote node, such as a network application 403d in FIG. 4d.

Various UI elements of applications 403 described above may be presented by one or more UI element handler components 433 in FIGS. 4a-c and/or by one or more template engines 423d in FIG. 4d. In an aspect, illustrated in FIGS. 4a-4c, UI element handler component(s) 433 of one or more applications 403 is/are configured to send representation information representing a visual interface element, such as operation bar 610 in FIG. 6, to a GUI subsystem 437. A GUI subsystem 437 may instruct a graphics subsystem 439 to draw the visual interface element in a region of display presentation space 602, based on representation information received from a corresponding UI element handler component 433.

Input may be received corresponding to a UI element via an input driver 441 illustrated in FIGS. 4a-c in various adaptations. For example, a user may move a mouse to move a pointer presented in a display presentation space 602 over an operation user interface element presented in an operation bar 610. A user may provide an input detected by the mouse. The detected input may be received by a GUI subsystem 437 via an input driver 441 as an operation or command indicator based on the association of the shared location of the pointer and the operation user interface element in display presentation space 602.

With reference to FIG. 2, block 202 illustrates that the method includes receiving resource information identifying a resource for processing by a hardware component in performing an operation. Accordingly, a system for presenting an indication of a cost of processing a resource includes means for receiving resource information identifying a resource for processing by a hardware component in performing an operation. For example, as illustrated in FIG. 3, cost advisor component 302 is configured for receiving resource information identifying a resource for processing by a hardware component in performing an operation. FIGS. 4a-d illustrate cost advisor components 402 as adaptations and/or analogs of cost advisor component 302 in FIG. 3. One or more cost advisor components 402 operate in execution environments 401.

In FIG. 4a, cost advisor component 402a is illustrated as a component of application 403a. In FIG. 4b, cost advisor component 402b is illustrated as component of network application agent 405b and/or browser 403b. In FIG. 4c, cost advisor component 402c is illustrated operating external to one or more applications 403c. Execution environment 401c includes cost advisor component 402c in cost alert subsystem 407c. In FIG. 4d, cost advisor component 402d is illustrated operating in network application 403d remote from a display device for presenting received information for updating a visual component. For example, cost advisor component 402d may operate in remote application provider node 506 while the received information is sent to a display device of user node 502 via network 504.

Receiving resource information identifying a resource may include receiving an indication to present a representation of the resource to a user via an output device, receiving an indication identifying the resource as an input to a component in an execution environment for performing an operation that includes processing the resource, detecting an access to the resource for processing by a program component, detecting an input corresponding to a user interface element including a representation of the resource, sending presentation information to present a representation of the resource to a user via an output device, and/or intercepting a communication for accessing the resource. In response to one or more of these and/or analogous events, a cost advisor component 402 in FIG. 4a-d may receive resource information identifying a resource.

Resource information may be received via a function, subroutine, and/or method invocation. Resource information may also be received via an interprocess communication (IPC) mechanism, via a message transmitted via a network, and/or via a shared region of a data store.

FIGS. 4a-c illustrate that a cost advisor 402 may interoperate with a user interface component, such as a user interface element handler component 433. The user interface component may present a representation of a resource for selecting by a user as an input to a program component for performing an operation. For example, a selectable representation of a resource may be presented in an explorer or navigation window, a list box, a spinner, a text input box, a file selection dialog, and/or any other user interface component for selecting an item by a user. The presentation may be via audio output with selection via a voice input device and/or other input device(s). Resource icons 608 in FIG. 6 may illustrate selectable representations of one or more resources. Exemplary resources for processing by a hardware component include some or all of a data file, an executable file, a database record, a network message, input data, and output data.

In an aspect, a resource icon 608 in FIG. 6 may represent an image and/or a video to be processed by a program component, such as application 403a in FIG. 4a, for presenting as a background of a display region, such as a desktop or an application background. Cost advisor component 402a may present a file navigation user interface to receive resource information identifying one or more images and/or videos for processing by an IPU and/or other hardware components included in execution environment 401a as an input to application 403a for performing the operation of presenting a desktop background.

In FIG. 4c, GUI subsystem 437c may receive resource information identifying an image and/or video to present in display presentation space 602 as desktop background 604. GUI subsystem 437c may interoperate with cost advisor component 402c to communicate resource information identifying the image and/or video resource.

Network application agent 405b in FIG. 4b and/or network application 403d in FIG. 4d may receive resource information for presenting a background for a window or tab presented via browser 403b. Cost advisor component 402b may, for example, be provided with resource information, and/or cost advisor component 402d may be provided with resource information. In an aspect, cost advisor component 402b and cost advisor component 402d may interoperate. In another aspect, cost advisor component 402b and cost advisor component 402d may operate independently. In still another aspect, one or the other of cost advisor component 402b and cost advisor component 402d may not be included in an adaption of one or the other of execution environment 401b and execution environment 401d.

In various aspects and adaptations of cost advisor 302 in FIG. 3, such as cost advisors 402 in FIGS. 4a-d, a cost advisor may be included in accessing and/or otherwise managing a resource. The cost advisor may receive resource information in response to an access to the resource. Resource information may be received through an invocation of a cost advisor 402 as a function, method, subroutine, and the like. The resource information may be received via a notification associated with a subscription to events associated with the resource and/or a program component for processing the resource. The resource information may be received via an interprocess communication mechanism (IPC) such as a message queue, a pipe, a software interrupt, and/or a hardware interrupt. The resource information may be received via a message received via a network.

Returning to FIG. 2, block 204 illustrates that the method further includes determining, for the resource, a measure of a processing cost, based on the operation, to provide an indication of the cost for processing the resource. Accordingly, a system for presenting an indication of a cost of processing a resource includes means for determining, for the resource, a measure of a processing cost, based on the operation, to provide an indication of the cost for processing the resource. For example, as illustrated in FIG. 3, cost monitor component 304 is configured for determining, for the resource, a measure of a processing cost, based on the operation, to provide an indication of the cost for processing the resource. FIGS. 4a-d illustrate cost monitor component 404 as adaptations and/or analogs of cost monitor component 304 in FIG. 3. One or more cost monitor components 404 operate in execution environments 401.

A metric defines a unit of measure. For example, an “inch” is a unit of measure for measuring length. A “kilowatt-hour” (kWh) is a unit of measurement in a metric for measuring an amount of energy. Instead of or in addition to measuring an amount a metric may measure a rate. “Kilowatts per hour” (kWh/h) is power metric for measuring a rate of energy used. A “measure” is a result of a particular measuring or measurement process. For example, 3 inches is a measure according to the length metric for inches, and 1000 kWh is a measure of an energy metric identifying an amount of energy. As used herein, a “measure of a processing cost” refers to a result of a measuring process for determining a processing cost according to a specified metric. Measuring may include estimating a measurement.

A processing cost may be determined and/or expressed by any metric directly and/or indirectly providing an indication of a processing cost. A metric for determining a processing cost in terms of electrical power may be determined by monitoring and measuring a rate of energy utilized by a hardware component that is included in processing a resource. The metric may represent the cost, for example, kilowatts per hour and/or in a monetary rate. In FIGS. 4a-d, cost monitor component 404 may be invoked to determine and/or otherwise identify a measure of a processing cost for processing a particular resource in performing an operation.

A metric may be specified for measuring and/or expressing a processing cost in a less direct manner. For example, with respect to energy cost, an energy cost may be measured by counting occurrences of an energy consuming activity, such as a disk read. From another perspective a metric based on disk reads may be a direct measure of a utilization cost resulting from processing one or more resources stored in a hard-drive.

Exemplary metrics for measuring processing cost include metrics for power, energy, monetary metrics, time metrics, kinetic or stored energy metrics, heat metrics, resistance metrics including mechanical and/or electrical resistance, metrics for measuring various energy and/or power consuming activities, metrics for measuring an environmental cost, health metrics, safety metrics, light metrics, metrics for measuring movement, metrics for measuring mass and/or weight, and/or metrics for measuring various opportunity costs.

A particular metric for determining a measure of a processing cost for a resource may be selected and/or otherwise identified based on various attributes of the resource, an operation that includes processing the resource, a program component for performing some or all of the operation, a hardware component included in processing the resource, a user, an organization, and/or a task; to name a few examples. For example, a metric such as a count of machine code instructions executed by an IPU may be specified and/or determined in performing a specified operation. An IPU based metric may be selected for measuring a cost of processing a resource where no output device is included in processing the resource. For an application or process that presents a user interface via a display component, a metric for measuring an amount and/or rate of heat and/or light generated by the display device may be specified.

A cost monitor component 404, in an aspect, may determine a measure of a processing cost based on metadata provided in and/or with one or more of a resource, a program component for performing an operation that includes processing the resource, and a hardware component included in performing an operation that includes processing the resource. A measure of a processing cost may be predetermined and located by cost monitor component 404 in and/or associated with a resource, a program component, and/or a hardware component. Cost monitor component 404 may access a table and/or other structure including predefined values for measures of the processing cost for a particular metric such as a change in temperature of a hardware component in Celsius and/or a time based cost represented in US dollars.

Cost monitor component 404 may look up and/or may otherwise identify a predefined value based on a type of a resource, a size of a resource, a source of energy, a hardware component, and/or a program component for processing a resource. The predefined value may be a measure of a processing cost and/or may be an input for determining a measure of a processing cost expressed according to an identified metric. For example, a predefined value may be multiplied by a measure of time that a resource may be processed by a program component to produce a time based metric such as kilowatt per hour or disk reads per minute.

In another aspect, cost monitor component 404 may determine a measure of a processing cost by calculating the measure according to the specified metric, and/or may interoperate with a sensor, such as thermometer, in measuring a cost of processing. Cost monitor component 404 may include and/or otherwise access one or more measurement components for determining a measure according to one or more metrics.

In FIG. 4a, cost monitor component 404a is illustrated operating in application 403a. Cost monitor component 404a may determine a measure of a processing cost for resources processed by application 403a. The resources may includes resources provided by application 403a to other applications, subsystems, and/or components operating in execution environment 401a and/or in another execution environment included in and/or otherwise provided by one or more devices.

For example, application 403a may present selection window 606 in FIG. 6. The resources processed by application 403a may include data, to send to another node, represented by resource icons 608. Cost monitor component 404a may determine a measure of a processing cost for transmitting the data to the other node via a network adapter in execution environment 401a via physical network media physically coupled to the network adapter and/or included in execution environment 401a. For example, cost monitor component 404a may be configured with and/or otherwise may determine a measure based on a count of bytes in the resources and in an encoded translation of the resources for transmitting.

In FIG. 4b, cost monitor component 404b is illustrated operating at least partially in network application agent 405b. Some or all of network application agent 405b may be received by browser 403b, operating in user node 502 in FIG. 5, from network application 403d in FIG. 4d operating in application provider node 506 in FIG. 5 as described above. FIG. 4d illustrates cost monitor component 404d operating in network application 403d. Cost monitor component 404b and/or cost monitor component 404d may determine a measure of a processing cost for resources processed by network application 403d and/or network application agent 405b. Cost monitor component 404b and/or cost monitor component 404d may be components in a cost monitor system distributed between network application agent 405b and network application 403d. Cost monitor component 404b and/or cost monitor component 404d may operate independently. Operating independently may include one of the cost monitor components operating in the absence of the other cost monitor component. Resources may include resources provided by network application agent 405b to browser 403b and/or extensions of browser 403b. The resources may further include resources provided to other nodes in network 504 by network application agent 405b and/or network application 403d. Network application agent 405b may interoperate with browser 403b to present selection window 606 in FIG. 6 in a browser window or tab (not shown). The resources processed may be represented by resource icons 608.

Cost monitor component 404b and/or cost monitor component 404d may determine a measure of a processing cost for processing one or more resources where processing the resources includes transmitting the resources via network 504 in FIG. 5. Transmitting resource data may include encoding, decoding, filtering, translating, and/or transforming some or all of the data in a resource in some manner. For example, a resource may be compressed prior to transmitting via network 504. Cost monitor component 404b may determine a metric based on a type of physical layer network included in network 504, may determine a metric based on an encoding, decoding, and/or other transformation, may determine a metric based on a manufacturer and/or type of network interface component, and/or may determine a metric based on network throughput data and/or other network attributes and/or metadata. The measure may be a cost for transmitting a web document via a network including a modem, a cost for retrieving image data in the document from a hard drive, a cost for decoding data received via network 504, and/or a cost for transmitting data over a secure network connection. Cost monitor component 404b and/or cost monitor component 404d may be configured with and/or otherwise to identify a predefined measure of a processing cost according to a metric selected by a developer of browser 403b and/or based on version information for browser 403b.

In FIG. 4c, cost monitor component 404c is illustrated operating in cost alert subsystem 407c. Cost alert subsystem 407c may be a subsystem of execution environment 401c that provides services to a number of program components operating in execution environment 401c and/or in another execution environment communicatively coupled via network 504 in FIG. 5. Cost monitor component 404c may determine measures of a processing cost(s) for various resources processed by various applications 403c operating in execution environment 401c. The resources may include resources provided to and/or otherwise accessible to applications 403c via various subsystems of execution environment 401c, such as a file system (not shown) and/or network stack 411c.

For example, selection window 606 in FIG. 6 may be presented as a document navigation window presented by execution environment 401c. “Op1” presented in operation bar 610 may invoke first application 403c1 for processing a currently selected resource, illustrated as resource icon 6082b. “Op2” in operation bar 610 may be a user interface control for invoking second application 403c2 for one or more selected resources represented by resource icons 608. Resources processed by first application 403c1 may include documents having various content types. Cost monitor component 404c may determine a measure of a processing cost for the documents expressed by a metric based on the format of the respective documents identified by a content type and based on an operation for processing the documents. The operation may be performed by application 403c1 and/or may be performed by one or more other components. For example, for a particular device a file system operation may be configured to be an operation for determining a measure of a processing cost for a resource processed by first application 403c1. In FIG. 4c, cost alert subsystem 407c may determine processing costs for resources freeing applications 403c from determining processing costs. Note that in an aspect; at least some of cost alert subsystem 407c may operate in a node other than the node included in and/or providing execution environment 401c. For example, some or all of the arrangement of components may be adapted to operate in execution environment 401d, which includes and/or is otherwise provided by application provider node 506.

Returning to FIG. 2, block 206 illustrates that the method yet further includes sending presentation information, based on the measure, for presenting, via an output device, the indication corresponding to a user detectable representation of the resource. Accordingly, a system for presenting an indication of a cost of processing a resource includes means for sending presentation information, based on the measure, for presenting, via an output device, the indication corresponding to a user detectable representation of the resource. For example, as illustrated in FIG. 3, cost presentation component 306 is configured for sending presentation information, based on the measure, for presenting, via an output device, the indication corresponding to a user detectable representation of the resource. FIGS. 4a-d illustrate cost presentation component 406 as adaptations and/or analogs of cost presentation component 306 in FIG. 3. One or more cost presentation components 406 operate in execution environments 401.

Presentation information for presenting a cost indication based on a measure of a processing cost may be sent via any suitable mechanism including an invocation mechanism, such as a function and/or method call utilizing a stack frame; an interprocess communication mechanism, such as a pipe, a semaphore, a shared data area, and/or a message queue; a register of a hardware component, such as an IPU register; and/or a network communication, such as an HTTP request and/or an asynchronous message.

In FIG. 4a, cost presentation component 406a may include a UI element handler component 433a for presenting a cost indication based on a measure of a processing cost. A UI element handler component 433a in cost presentation component 406a may send presentation information for presenting the cost indication by invoking GUI subsystem 437a to present the cost indication along with a representation of the resource presented via an output device. Alternatively or additionally, cost presentation component 406a may interoperate with a user interface handler component 433a that presents some or all of the representation of the resource in order to present the cost indication. The cost indication may be represented by an attribute of a UI element. For example, cost presentation component 406a may send color information to present a representation of the resource in black and white rather than color. The color may be a cost indication for the resource. Black and white may indicate that the resource is less costly, according to a measure determined according to a particular metric, than resources presented in one or more other colors specified as cost indications based on the metric.

Presentation information representing a cost indication based on a measure of a processing cost may include information for changing a border thickness in a border in a resource representation. The border thickness may be a cost indication. The presentation information may be sent, for example by GUI subsystem 437a in FIG. 4a, to present an indication of the measure of the processing cost for the resource. The measure is determined based on a specified operation and is determined according to a specified metric. Sending the presentation information may include translating a first measure of a processing cost based on a first metric to a second measure based on a second metric. For example, a measured change in temperature of an IPU may be translated to a second measure based on a metric such as border thickness or border color. That is, a change in temperature may be represented and/or otherwise indicated by a border thickness of a user interface element.

FIG. 6 illustrates desktop background 604 presented with a patterned border in a region of display presentation space 602. In an aspect, a measure of a processing cost based on an energy metric may be presented as a matching indication indicating whether an amount of energy used in processing a resource matches a specified energy condition of a hosting device and/or component. FIG. 6 illustrates two energy measure indications. A patterned indication may be presented in and/or with desktop background 604, desktop resource icon 6081a, and desktop resource icon 608mb. The patterned indication may be specified to indicate that a measure of energy for processing an associated resource does not match a specified energy condition. Another color and/or pattern may be configured as an indication that indicates a match. In FIG. 6, resources presented normally may indicate that a determined measure of energy for the normally presented resources matches the energy condition. In an aspect, an energy condition may be based on a source of energy for a device such as a battery versus a connection to an electrical socket. In another aspect, an energy condition may be based on a determined a rate energy consumption by a device and/or a component of a device.

FIG. 6 also illustrates presenting a cost indication based on a metric for measuring a particular cost of processing as a numeric indication based on measures determined for the respective resources illustrated by resource icons 608. For example, the illustrated indications in FIG. 6 are based on a five-point scale providing relative indications of a processing cost for the respective resources. An indication of “5” may be defined as a cost indication for a most expensive resource or resources for processing according the metric. A “1” indication may indicate resources that require the least cost according to the metric as presented according to the five-point scale.

A containing window or pane of a presented resource representation may be provided by a library routine of GUI subsystem 437c. Cost presentation component 406c may change a user detectable attribute of the containing UI element. For example, cost presentation component 406c may send presentation information for a cost indication based on a metric for measuring a monetary cost of time.

A region of display presentation space 602 may be designated for presenting a resource having a cost that matches a specified condition. A position on a screen may be a cost indication. For example, higher-cost resources may be placed relatively closer to the bottom of a screen than relatively lower-cost resources. In another aspect, an orientation of a UI element representing and/or associated with a resource may be defined as a cost indication based on a specified measure according to particular metric. Variations in other user detectable attributes may be configured as indications for various metrics in other aspects.

A cost presentation component 406 may change a pointing device representation, such as a mouse pointer, when it approaches and/or is in a location of a presented resource, as a cost indication based on a measure according to a particular metric for processing a resource represented by a UI element in the location. For example, different colors of the pointer may be defined as different indications associated with different measures of a processing cost. In one aspect, a resource may be automatically selected when a cost condition based on a measure of a processing cost is met. Thus automatic selection may be a cost indication.

To present a cost indication, cost presentation component 406c may interoperate with a different output device than the output device presenting a representation of the resource. For example, a pointing device may also be a tactile output device. Cost presentation component 406c may instruct the pointing device to vibrate at a various frequencies to provide different indications based on different measures determined according to a metric for measuring a processing cost.

In FIG. 4d, cost presentation component 406d in network application 403d may send information via a response to a request and/or via an asynchronous message to a client, such as browser 403b and/or network application agent 405b, to present a user detectable indication of a measure of a processing cost for a resource.

In various aspects a user detectable indication of a measure of a processing cost may include a change in an attribute of a UI element representing a resource, such as z-order, a level of transparency, a location in a presentation space, a size, a shape, and/or input focus state; and/or may include a new UI element, such as a pop-up message and/or a fly-over UI element. A location for presenting the indication may be based on a location of the representation of the resource and/or may be a location determined prior to and/or independent of the location of the representation of the resource.

A user detectable indication of a measure of a processing cost for a resource may be presented on a same output device as the representation of the resource and/or on a different output device. The measure may be presented via a visual output device, an audio output device, a tactile output device, and/or another type of output device.

A user detectable indication of a measure of a processing cost for a resource may be presented as directed by cost presentation component 406 for a specified duration of time and/or until a specified event is detected, and/or may include a pattern of changes presented to a user. For example, an indication of a measure of a processing cost may be presented until a user input is detected that corresponds to the indication, forcing a user to acknowledge the indication to make it disappear.

The method illustrated in FIG. 2 may include additional aspects supported by various adaptations and/or analogs of the arrangement of components in FIG. 3. In various aspects, receiving resource information may include receiving resource information in response to a detected user input for presenting a resource, performing an operation that includes processing a resource, and/or selecting a resource as described above. Receiving the resource information may include receiving an identifier of the resource and/or receiving operation information identifying an operation that includes processing the resource.

Receiving resource information identifying a resource may include intercepting a communication for performing an operation, detecting an access for retrieving the resource, reading a message recording at least one of an access to the resource and a request for performing an operation, identifying a mapping identifying the type of the resource and an operation, and/or detecting a change in a program component for performing an operation, a change in the resource, and a change in a hardware component included in processing the resource. To receive resource information, cost advisor component 402 may be configured to interoperate with various components, including a file system, a data store, a data storage device, GUI subsystem 437, an input driver 441, network stack 411, and/or application protocol component 413, to name a few examples.

Access to a resource may be detected based on detecting an access to a semaphore, a lock, a data storage location, a component of a input subsystem, a component of a presentation subsystem, a storage subsystem, a component of networking subsystem, a component of a graphics subsystem, a component of an audio subsystem, a display adapter, a display device, an audio adapter, an audio output device, a tactile presentation subsystem, a tactile output device, an access control component, a serialization component, a synchronization component, a thread, an input device driver, an input device, another application, a code library, a database, a service operating in a remote node via a network, text data, image data, audio data, tactile data, a message formatted according to a communication protocol, a service, a presence entity, a subscription, a software component, a hardware component, a transaction, a media stream, a location, a measuring device, data, an instruction, a persistently stored resource, a resource stored in volatile storage, a network resource, a preexisting resource, a dynamically generated resource which already exists, a service for generating the resource, a font, an encoding, a format, a mechanical resource, and/or an optical resource, to name some examples. Image data may include and/or may be included, for example, in a still image, a video, a background image, and/or an image for representing another resource. Audio data may include, for example, some or all of a song, a voice message, and/or a sound for indicating an event.

A resource may be accessed from a data storage location in, for example, a processor memory, a secondary storage, a memory of a hardware adapter, a removable data storage medium, and/or a remote data store. When a resource includes image data, the image data may include, for example, some or all of a still image, a video, a background image, and/or an image for representing another resource. When a resource includes audio data, the audio data may include, for example, some or all of a song, a voice message, and a sound for indicating an event.

A metric for determining a measure of a processing cost for a resource may be selected and/or otherwise identified based on a type of the resource and/or an operation to perform that includes processing the resource. A metric for measuring a processing cost for a resource may be based on at least one of the resource, an operation included in processing the resource, a hardware component included in performing an operation that includes processing the resource, a user, a group, a role, a task, a time, and a location. For example, a cost monitor component 404 may monitor an amount of energy provided to a display device for presenting an image resource. In another example, a cost monitor component 404 may determine a measure of a processing cost according to a metric based on a count of bytes in a file resource for transmitting a resource via a network.

Exemplary resources include some or all of a file, a database record, a document, a media stream, a digital image, a communication communicated between at least two communicants, and a log. A resource may include an executable instruction. Exemplary hardware components that may be included in processing a resource include an IPU, an output device, a storage device, an input device, a networking component, a bus, a physical processor memory, and/or a switching fabric.

Various aspects and adaptations of cost monitor component 304 in FIG. 3 may determine a measure of a processing cost for a metric based on a rate of electrical energy, stored energy, mechanical resistance, electrical resistance, time, a count of a particular energy related event, money, an environmental impact, a health impact, a change in size, a change in mass and/or weight, a safety impact, heat, light, and/or movement. Correspondingly, various aspects and adaptations of cost monitor component 304 may determine a measure of electrical energy, a measure of stored energy, a measure of mechanical resistance, a measure of electrical resistance, a measure of time, a count of a particular event, a measure of monetary cost, a measure of heat, a measure of light, a measure of distance, a measure of mass, a measure of size, and/or a measure of weight.

A cost monitor component 304 may count and/or otherwise receive count information identifying a count of IPU cycles, disk spins, data read operations, data write operations, refreshes of at least a portion of a presentation space, display refreshes, data transmitted via a network, data received via a network, and/or a measure of human movement.

A measure of human movement may be based on at least one of a measure of dispersion of key presses; a pattern and frequency of movement of a tracking device; a count of at least one of key presses, squeezes, pushes, and pulls; changes between lower case and upper case, a count of particular numerical digits entered, and a count of different input devices providing information in response to user input.

A metric for determining a measure of a processing cost for a resource may be based on a maximum, a minimum, a mean, a median, a mode, a measure of variance, a measure of dispersion, a rate of change, a threshold, a continuous function, a discrete value from a series of discrete values, a relative measure, and/or an absolute measure. Cost monitor component 304 may calculate any of the above in various aspects and adaptations and/or may interoperate with another component for determining any of the listed information.

Determining a measure of a processing cost for a resource may be based on a previous determination of a measure of a processing cost for the resource and/or for another resource. An adaption of cost monitor component 304 in FIG. 3 may determine a measure of a processing cost based on a history of previously determined measures.

A metric for determining a measure of a processing cost may be based on user input and/or on configuration information received from a user. Determining a measure of a processing cost may include sending a message via a network to a node for determining the measure, and receiving a response via the network identifying the measure.

A cost indication for a resource may be presented in a representation of the resource presented via an output device. A cost presentation component 406 in FIG. 4a-d may present resource icon 6081a in FIG. 6 including a cost indication illustrated as a visible pattern.

In an aspect, a representation of a resource may be user selectable when a cost condition, such as an energy condition, based on a measure of a processing cost, is met and not user selectable when the cost condition is not met. For example, in FIG. 6 normally presented resource icons 608 may be presented as selectable as directed by cost presentation component 406. Pattern icons such as resource icon 608mb may be presented as non-selectable by cost presentation component 406, so that user input corresponding to resource icon 608mb is not processed as a selection of the resource, as analogous input for normally presented icons is processed as a selection.

In an aspect, a user input for selecting a resource may be detected. A warning indication may be presented, in response to receiving the selection, when a cost condition, for example based on an amount of energy utilized in at least a portion of processing the resource, is not met. A cost presentation component 406 may direct a UI element handler component 433 to present a warning when cost monitor component 404 determines that an energy condition is not met for the selected resource, based on a determined measure of a processing cost for the resource. The measure of the processing cost may be based on an energy metric that may include a power metric.

An indication of a measure of a processing cost for a resource may include presenting a representation of a resource in a plurality of representations of resources according to an order of respective measures of processing costs determined for the resources in the plurality.

Presentation information for presenting a cost indication may be sent in a message via network to a node operatively coupled to an output device. Cost presentation component 406d in FIG. 4d operating in application provider node 506 in FIG. 5 may send presentation information in response to a request from network application agent 405b in FIG. 4b operating in user node 502.

As described above and illustrated in FIG. 6, a cost indication for a resource may be presented via a user detectable attribute in the representation of the resource. A cost indication may be presented in a user interface element including the representation of the resource and/or a user interface element separate from a user interface element including the representation of the resource.

Presentation information for presenting a cost indication for a resource may be sent in response to detecting an access to the resource and/or detecting an indicator for performing an operation that includes processing the resource. Detecting an access may include receiving a specified user input for accessing at least one of the resource and a program component included in processing the resource. For example, a UI element handler component 433 corresponding to a resource icon 608 in FIG. 6 may detect a particular mouse gesture configured to instruct the UI element handler component 433 to present a cost indication determined by cost monitor component 404 for the resource represented by the resource icon 608. The cost indication may be presented by the UI element handler 433 in response to received information based on the mouse gesture detected by a GUI subsystem 437 via input driver 441. The cost indication may be predetermined in one aspect. In another aspect, a cost monitor component 404 may determine a measure of a processing cost for generating the cost indication in response to the detected mouse gesture.

Presentation information for presenting a cost indication for a resource may be sent in response to a change in a measure of a processing cost associated with another resource. For example, cost alert subsystem 407c in FIG. 4c may monitor a level of energy in a battery, as another resource, providing energy for a handheld device. Cost alert subsystem 407c may invoke cost monitor component 404c in response to detecting a battery energy level falling below a specified threshold. Cost monitor component 404c may recalculate and/or otherwise determine a measure of a processing cost for one or more resources in response to the change in battery state. Cost monitor component 404c may provide changed measures of the processing cost to cost presentation component 406c. Cost presentation component 406c may generate and send presentation information to present cost indications in response to the change in battery state.

Sending presentation information for presenting a representation of a measure of a processing cost may include receiving selection information identifying the resource in response to a detected user input corresponding to a presentation of the resource. In response, the resource may be identified to a program component for performing a specified operation.

In an aspect, an energy condition may be specified. A measure of a processing cost determined for a resource may be determined for evaluating an energy condition to determine whether the energy condition is met. An energy condition may be identified for evaluating and/or may be evaluated based on a source of energy, an amount of energy available, an amount of energy available in a battery and/or other energy store, a rate of energy used and/or currently being used for processing another resource, a location of the device, and a time required for restoring an energy store to a specified state, to name a few examples. A location of a device may be a location with respect to another location for charging or changing energy sources.

In response to determining whether an energy condition is met for a resource, a representation of the resource presented by an output device may be presented as user selectable or not user selectable. For example, in FIG. 4c when an amount of energy available from a battery in a mobile device falls below a specified threshold, files over a specified size may not be presented or may be presented but not selectable for attaching to an email by an email application represented by second application 403c2. In FIG. 4b and in FIG. 4d, one or both of cost monitor component 404b and cost monitor component 404d may receive information identifying a monetary cost of transmitting data via a current network access provider. Based on the cost, certain resources may be presented as selectable for certain operations including transmitting data in the resources and may be presented as not selectable for other network operations based on one or more cost conditions associated with the operations and/or the resources.

As described above, in another aspect, selection information may be received from a user to select a resource. Instead of preventing a resource from being selected for an operation, a warning indication may be presented to the user based on whether an energy condition evaluated based on the resource is met or not met. This allows the user to determine whether processing the resource in performing the operation is worth the cost as determined and/or represented by a metric.

A cost indication based on a measure of a processing cost for a resource may be represented via an output presentation device in a presentation of a resource. Resource icon 6081a illustrates a patterned icon representing a resource where the pattern is a cost indication. A cost indication may be included in an order of resources in a plurality of resources where the order is based on measures of a processing cost for the respective resources.

A representation of a measure of a processing cost for a resource may be presented in and/or may include a window, a textbox, a button, a check box, a radio button, a slider, a spin box, a list box, a drop-down list, a menu, a menu item, a toolbar, a ribbon, a combo box, a tree view, a grid view, a navigation tab, a scrollbar, a label, a tooltip, a balloon, and/or a dialog box.

As described above with respect to FIG. 4d and also with respect to FIG. 4c, presentation information for presenting a cost indication may be sent via a network to a node for presentation via an output device of the remote node.

The presentation information may include color information, font information, size information, location information, and/or transparency information for representing the measure. The representation of the measure may be represented by a user detectable attribute in the presentation of the resource.

As described above, a representation of a measure of a processing cost for a resource may be in a user interface element including the presentation of the resource and/or may be in a user interface element separate from a user interface element including the presentation of the resource. The scale from one to five in FIG. 6 illustrates cost indications presented apart from resource icons 608 representing resources.

A cost indication may be presented by sending presentation information, in response to detecting an access to the resource and/or detecting an indicator for performing the operation. In another aspect, an input may be predefined for indicating that a cost indication for a resource is to be presented. For example, a keyboard may include a “hotkey” defined by an execution environment to indicate that a measure of a processing cost is to be presented for a selected resource and/or for one or more resources in a UI element that has input focus, for example.

Presentation information for a cost indication for a resource may be sent in response to a change in a measure of a processing cost associated with another resource and/or a change in an energy condition that is based on the measure of a processing cost. For example, the presentation information may be sent in response to a change in a source of energy, an energy provider, a change in location, and/or a change in users, to name a few examples.

To the accomplishment of the foregoing and related ends, the descriptions and annexed drawings set forth certain illustrative aspects and implementations of the disclosure. These are indicative of but a few of the various ways in which one or more aspects of the disclosure may be employed. The other aspects, advantages, and novel features of the disclosure will become apparent from the detailed description included herein when considered in conjunction with the annexed drawings.

It should be understood that the various components illustrated in the various block diagrams represent logical components that are configured to perform the functionality described herein and may be implemented in software, hardware, or a combination of the two. Moreover, some or all of these logical components may be combined, some may be omitted altogether, and additional components may be added while still achieving the functionality described herein. Thus, the subject matter described herein may be embodied in many different variations, and all such variations are contemplated to be within the scope of what is claimed.

To facilitate an understanding of the subject matter described above, many aspects are described in terms of sequences of actions that may be performed by elements of a computer system. For example, it will be recognized that the various actions may be performed by specialized circuits or circuitry (e.g., discrete logic gates interconnected to perform a specialized function), by program instructions being executed by one or more instruction-processing units, or by a combination of both. The description herein of any sequence of actions is not intended to imply that the specific order described for performing that sequence must be followed.

Moreover, the methods described herein may be embodied in executable instructions stored in a computer readable medium for use by or in connection with an instruction execution machine, system, apparatus, or device, such as a computer-based or processor-containing machine, system, apparatus, or device. As used here, a “computer readable medium” may include one or more of any suitable media for storing the executable instructions of a computer program in one or more of an electronic, magnetic, optical, electromagnetic, and infrared form, such that the instruction execution machine, system, apparatus, or device may read (or fetch) the instructions from the computer readable medium and execute the instructions for carrying out the described methods. A non-exhaustive list of conventional exemplary computer readable media includes a portable computer diskette; a random access memory (RAM); a read only memory (ROM); an erasable programmable read only memory (EPROM or Flash memory); optical storage devices, including a portable compact disc (CD), a portable digital video disc (DVD), a high definition DVD (HD-DVD™), and a Blu-ray™ disc; and the like.

Thus, the subject matter described herein may be embodied in many different forms, and all such forms are contemplated to be within the scope of what is claimed. It will be understood that various details may be changed without departing from the scope of the claimed subject matter. Furthermore, the foregoing description is for the purpose of illustration only, and not for the purpose of limitation, as the scope of protection sought is defined by the claims as set forth hereinafter together with any equivalents.

All methods described herein may be performed in any order unless otherwise indicated herein explicitly or by context. The use of the terms “a” and “an” and “the” and similar referents in the context of the foregoing description and in the context of the following claims are to be construed to include the singular and the plural, unless otherwise indicated herein explicitly or clearly contradicted by context. The foregoing description is not to be interpreted as indicating that any non-claimed element is essential to the practice of the subject matter as claimed.

I claim:

1. A method for presenting an indication of a cost of processing a resource, the method comprising:
receiving resource information identifying a resource for processing by a hardware component in performing an operation;
determining, for the resource, a measure of a processing cost, based on the operation, to provide an indication of the cost for processing the resource; and
sending presentation information, based on the measure, for presenting, via an output device, the indication corresponding to a user detectable representation of the resource.

2. The method of claim 1 wherein the resource information is received in response to a detected user input at least one of identifying the resource and identifying an operation that includes processing the resource.

3. The method of claim 1 wherein the measure is determined according to a metric based on at least one of electrical power, electrical energy, stored energy, mechanical resistance, electrical resistance, time, a count of a particular event, money, size, mass, distance, weight, heat, light, and movement.

4. The method of claim 1 wherein the measure includes at least one of a measure of electrical power, a measure of electrical energy, a measure of stored energy, a measure of mechanical resistance, a measure of electrical resistance, a measure of time, a count of a particular event, a measure of a monetary cost, a measure of heat, a measure of light, a measure of distance, a measure of mass, a measure of size, and a measure of weight.

5. The method of claim 4 wherein the count is based on at least one of instruction-processing unit cycles, disk spins, data read operations, data write operations, refreshes of at least a portion of a presentation space, display refreshes, data transmitted via a network, data received via a network, and a measure of human movement.

6. The method of claim 5 wherein the measure of human movement is based on at least one of a measure of dispersion of key presses; a pattern and frequency of movement of a tracking device; and a count of at least one of key presses, squeezes, pushes, and pulls; changes between lower case and upper case, a count of numerical digits, and a count of different input devices providing information in response to user input.

7. The method of claim 1 wherein a metric for determining the measure is identified based on at least one of the resource, the operation, the hardware component included in performing the operation, a user, a group, a role, a task, a time, a location, a device for performing the operation, and device for providing the resource.

8. The method of claim 7 wherein the measure is determined based on a user input for identifying the metric.

9. The method of claim 1 wherein determining the measure is based on locating a predefined measure based on at least one of the resource and the operation.

10. The method of claim 1 wherein determining the measure includes sending a message via a network to a node for determining the measure; and receiving a response via the network identifying the measure.

11. The method of claim 1 wherein determining the measure further includes determining whether a specified energy condition is met based on the measure.

12. The method of claim 11 wherein the representation of the resource is user selectable when the energy condition is met and is not user selectable when the energy condition is not met.

13. The method of claim 11 further comprising:
receiving selection information identifying the resource in response to a detected user input corresponding to the representation of the resource; and
presenting a warning indication, in response to receiving the selection information, when the energy condition is not met.

14. The method of claim 1 wherein the indication is included in the representation of the resource.

15. The method of claim 1 further comprises presenting the representation of the resource in a plurality of representations of resources according to an order based on a metric the measure represents.

16. The method of claim 1 wherein sending the presentation information includes sending a message to a node operatively coupled to the output device.

17. The method of claim 1 wherein the indication is presented in response to a user input predefined for presenting the indication.

18. The method of claim 1 wherein the presentation information is sent in response to a change in at least one of a cost condition and a measure of a processing cost associated with another resource.

19. A system for presenting an indication of a cost of processing a resource, the system comprising:
a cost advisor component, a cost monitor component, and a cost presentation component adapted for operation in an execution environment;
the cost advisor component configured for receiving resource information identifying a resource for processing by a hardware component in performing an operation;
the cost monitor component configured for determining, for the resource, a measure of a processing cost, based on the operation, to provide an indication of the cost for processing the resource; and
the cost presentation component configured for sending presentation information, based on the measure, for presenting, via an output device, the indication corresponding to a user detectable representation of the resource.

20. A computer-readable medium embodying a computer program, executable by a machine, for presenting an indication of a cost of processing a resource, the computer program comprising executable instructions for:
receiving resource information identifying a resource for processing by a hardware component in performing an operation;
determining, for the resource, a measure of a processing cost, based on the operation, to provide an indication of the cost for processing the resource; and
sending presentation information, based on the measure, for presenting, via an output device, the indication corresponding to a user detectable representation of the resource.
